(19) United States
(12) Patent Application Publication
(10) Pub. No.: US 2006/0057846 A1
(43) Pub. Date: Mar. 16, 2006

(54) Composition for use as sanitary earthenware material, method for production thereof, method for manufacturing sanitary earthenware using said composition

(75) Inventors: Hidemi Ishikawa, Kitakyushu-Shi (JP); Katsuhiro Kawakami, Kitakyushu-Shi (JP); Tsuyoshi Ozeki, Kitakyushu-Shi (JP); Takachika Arakawa, Kitakyushu-Shi (JP); Mitsuyoshi Machida, Kitakyushu-Shi (JP)

Correspondence Address: HELLER EHRMAN WHITE & MCAULIFFE LLP, 1717 RHODE ISLAND AVE, NW, WASHINGTON, DC, 20036-3001, US

(73) Assignee: TOTO LTD., Kitakyushu-Shi (JP)

(21) Appl. No.: 10/528,099

(22) PCT Filed: Sep. 26, 2003
(86) PCT No.: PCT/JP03/12371

§ 371 Date: Mar. 16, 2005

(30) Foreign Application Priority Data
Sep. 27, 2002 (JP) 2002-283965
Mar. 28, 2003 (JP) 2003-090864

(51) Int. Cl. H01L 21/302; H01L 21/461

(52) U.S. Cl. 438/689

(57) ABSTRACT

Disclosed are a composition for a sanitary ware body for use in slip casting, possessing excellent long-term storage stability, transportability and slurry regeneration, a production process of the same, and a production process of a sanitary ware using the composition for a sanitary ware body. This composition for a sanitary ware body comprises agglomerate of a raw material powder for said sanitary ware body and has a water content of 0 (zero) to 25% by weight and a 50% average particle diameter of 1 to 15 μm on a number basis of the powder. A slurry of a raw material for a sanitary ware body for use in slip casting can be prepared by adding water to the composition for a sanitary ware body and stirring the mixture.

### BACKGROUND OF THE INVENTION

1. Field of the Invention

The present invention relates to a composition for a sanitary ware body for use in slip casting, a process for producing the same, and a process for producing a sanitary ware using said composition.

2. Background Art

In the production of sanitary wares, slip casting is generally adopted for the production of green bodies. This is because sanitary wares are relatively large and have a complicated shape. Slip casting is, for example, carried out as follows. A suitable amount of water is added to the raw material for a sanitary ware body to render the raw material fluid. Next, the raw material, to which water has been added, is mixed and ground in a ball mill or the like to prepare a slurry. The slurry thus obtained as such is poured into a slip casting mold. In this way, the raw material for a sanitary ware body for use in slip casting is slurried and, in this state without being solidified, is then used in the step of slip casting.

On the other hand, in the production of pottery or ceramic whiteware, such as tiles, in which a green body is prepared by plastic pressing, the raw material for a pottery or ceramic whiteware body is subjected to the step of plastic pressing in the form of a plastic pressing body prepared by dehydrating a slurry of the raw material, that is, in the form of a solid.

Japanese Patent Laid-Open No. 40777/1996 discloses a method in which a slurry composition for plastic shaping is dehydrated to prepare a body for plastic shaping which is then subjected to plastic shaping such as extrusion or power jiggering to prepare a green body.

### SUMMARY OF THE INVENTION

The present inventors have now found that, in a slurry of a raw material for a sanitary ware body for use in slip casting, reducing the water content to 0 (zero) to 25% by weight can realize stable storage of the raw material for a long period of time, significant reduction in a load on raw material transfer and storage, and immediate regeneration of a slurry for a sanitary ware body in a very simple manner which is then used for slip casting.

Accordingly, an object of the present invention is to provide a composition for a sanitary ware body for use in slip casting, possessing excellent long-term storage stability, transportability and slurry regeneration, a production process of the same, and a production process of a sanitary ware using the composition for a sanitary ware body.

According to one aspect of the present invention, there is provided a composition for a sanitary ware body for use in slip casting, comprising agglomerates of a raw material powder for said sanitary ware body and having a water content of 0 (zero) to 25% by weight, wherein

said powder has a 50% average particle diameter of 1 to 15 μm on a number basis.

According to another aspect of the present invention, there is provided a process for producing a composition for a sanitary ware body for use in slip casting, said process comprising the steps of:

providing a raw material for a sanitary ware body;

adding water to the raw material for a sanitary ware body;

grinding the raw material for a sanitary ware body with water added thereto to prepare a slurry for slip casting; and

dehydrating and/or drying the slurry for slip casting to prepare the composition for a sanitary ware body.

According to a further aspect of the present invention, there is provided a process for producing a sanitary ware, comprising the steps of:

adding water to the above composition for a sanitary ware body and stirring the mixture to regenerate the slurry;

pouring the slurry into a slip casting mold and allowing the slurry to cast on the mold;

taking the resultant green body out of the mold;

drying the green body;

coating glaze onto the dried green body; and

firing the glaze-coated green body.

### BRIEF DESCRIPTION OF THE DRAWINGS

FIG. 1 is a perspective view of a Western-style toilet bowl as prepared in Examples 6 and 7 and Comparative Example 2;

FIG. 2 is a side view of the Western-style toilet bowl shown in FIG. 1; and

FIG. 3 is a front view of the Western-style toilet bowl shown in FIG. 1.

### DETAILED DESCRIPTION OF THE INVENTION

Definition

The term “water content” as used herein refers to the fraction of the amount of water in the total weight of the whole water-containing solid which is calculated by the following equation:
Z=[(W−W_{D})/W_{D}]×100
wherein

Z: water content, %;

W: mass of sample before drying, g; and

W_{D}: mass of sample after drying for 24 hr at 110° C., g.

In the present invention, the expression “50% average particle diameter on a number basis” refers to the diameter of particles at the time when the cumulative number of small particles as counted from smaller particles side has reached 50% of the total number of particles as determined based on data on the particle size distribution measured with a laser diffraction-type particle size distribution analyzer.

In the present invention, the expression “50% average particle diameter on a weight basis” refers to the diameter of particles at the time when the cumulative weight of small particles as measured from smaller particles side has reached 50% of the total weight of particles as determined based on data on the particle diameter distribution on a weight basis measured by a sieving method. In the present invention, the particle diameter distribution on a weight basis may be measured with a dry sieving apparatus according to JIS Z 8815 (1994). This JIS, together with English translation thereof, is easily available from Japanese Standards Association (1-24, Akasaka 4-chome, Minato-ku, Tokyo, Japan). Specifically, a sieving apparatus equipped with test sieves specified in JIS Z 8801 is provided, and a single test sieve or a plurality of test sieves put on top of each other is vibrated for sieving. The sieving time is the time which has elapsed between the start of the sieving and the time when the mass of a group of particles which has passed through the sieve per minute reaches not more than 0.1% of the mass of the charged sample. The total of the mass of each oversize and the mass of undersize of the smallest aperture sieve as measured after the completion of the sieving should be within ±2% of the mass of the charged sample. Particles which clog meshes are removed by turning the sieve upside down so that the backside of the sieving net faces upward, and removing the particles by a clogging eliminating brush. The particles which cause clogging of the meshes are regarded as the oversize.

Composition for sanitary ware body

The composition for a sanitary ware body according to the present invention is a composition which can form into a raw material slurry for a sanitary ware body by adding water to the composition and stirring the mixture. The composition for a sanitary ware body according to the present invention is usable in slip casting. This composition comprises agglomerates of a raw material powder for the sanitary ware body and has a water content of 0 (zero) to 25% by weight. The powder constituting the agglomerate has a 50% average particle diameter of 1 to 15 μm on a number basis. This composition for a sanitary ware body according to the present invention enables a raw material for a sanitary ware body for slip casting to be stably stored for a long period of time. Further, a burden on raw material transfer and storage can be significantly reduced. Furthermore, a slurry for a sanitary ware body can be immediately regenerated from the composition for - a sanitary ware body by a very simple method and can be used for slip casting.

Specifically, since the composition for a sanitary ware body according to the present invention has a low water content of 0 (zero) to 25% by weight, as compared with the slurry before the solidification, the volume and the weight can be significantly reduced. Therefore, a burden on raw material transfer and storage can be significantly reduced, and the efficiency of the transfer and storage can be increased. The water content of the slurry is generally about 40 to 60%.

The composition for a sanitary ware body according to the present invention is not a slurry and, thus, is free from a problem, which is likely to occur in the slurry, that is, a change in slurry properties during storage for a long period of time, for example, precipitation of solid matter. That is, the raw material for a sanitary ware body can be stably stored for a long period of time. The water content of powder provided after drying may somewhat fluctuate during storage and keeping. The fluctuation in water content of the powder, however, poses no problem because, in reslurrying, water is added to the powder to regulate the amount of water in the regenerated slurry.

Further, in the composition for a sanitary ware body according to the present invention, the powder constituting the agglomerate has a 50% average particle diameter of 1 to 15 μm on a number basis. This particle diameter distribution corresponds to the particle diameter distribution which is commonly possessed by a slurry for a sanitary ware body for use in slip casting. By virtue of this, before use in slip casting, a slurry for a sanitary ware body can be immediately regenerated from the composition according to the present invention by a very simple method in which water is added and the mixture is stirred. Therefore, unlike the case where raw materials for a sanitary ware body such as pottery stone, feldspar, and clay are stored as they are, the composition according to the present invention can rapidly cope with a sudden increase in a demand.

The raw material for a sanitary ware body according to the present invention is not particularly limited so far as the material is a body material commonly used in the production of sanitary wares, and examples thereof include pottery stone, silica rock, feldspar, kaolin, and clay.

The mixing ratio of ingredients in the raw material for a sanitary ware body is not particularly limited. A preferred example thereof is as follows.

| Ingredients | Preferred range | More preferred range |
|---|---|---|
| Pottery stone: | 35 to 70 wt % | 50 to 55 wt % |
| (kaolin, sericite, | | |
| pyrophyllite, etc.) | | |
| Flux: | 10 to 40 wt % | 20 to 30 wt % |
| (albite, potash | | |
| feldspar, nepheline, | | |
| petalite, dolomite, | | |
| etc.) | | |
| Clay: | 10 to 50 wt % | 20 to 25 wt % |

In a preferred embodiment of the present invention, the water content of the composition for a sanitary ware body is 0 (zero) to 9% by weight, more preferably 3 to 7% by weight. When the water content is within the above-defined water content range, the composition has excellent fluidity. Further, when a slurry is regenerated from the composition and used in slip casting, a satisfactory casting thickness can be ensured. A water content in the range of 3 to 7% by weight is advantageous in that dusting is less likely to occur and, when a slurry is regenerated from the composition, the viscosity of the slurry before the solidification can be realized by simply adding water.

In another preferred embodiment of the present invention, the water content of the composition for a sanitary ware body is preferably in the range of 15 to 25% by weight. When the water content is in the above-defined water content range, the step of drying, which requires a lot of time, can be omitted in the production of the composition. Further, when the slurry is dehydrated by a filter press to prepare the composition, there is no need to use high pressure. Therefore, a burden on filter cloth and machine can be reduced. Further, since the composition is less likely to be provided in a large mass form, workability at the time of storing and dissolution at the time of reslurrying are excellent.

In the composition for a sanitary ware body according to the present invention, the 50% average particle diameter on a number basis of the powder constituting the agglomerate is 1 to 15 μm, preferably 1 to 10 μm, more preferably 5 to 10 μm. In a preferred embodiment of the present invention, preferably 45 to 70%, more preferably 50 to 65%, of the whole powder constituting the agglomerate has a size of not more than 10 μm on a number basis. This particle diameter distribution corresponds to a particle diameter distribution which is commonly possessed by a slurry for a sanitary ware body used in slip casting. By virtue of this, before use in slip casting, a slurry for a sanitary ware body can be immediately regenerated from the composition according to the present invention by a very simple method in which water is added and the mixture is stirred.

In the composition for a sanitary ware body according to the present invention, the 50% average particle diameter on a number basis of the raw material powder for a sanitary ware body and the proportion of particles having a size of not more than 10 μm can be measured as follows. At the outset, water is added to the composition for a sanitary ware body, and the mixture is stirred to disintegrate the agglomerate. Thus, a slurry containing homogeneously dispersed raw material powder for a sanitary ware body is prepared. Next, the particle size distribution of the slurry thus obtained is measured with a laser diffraction-type particle size distribution analyzer. The 50% average particle diameter on a number basis, that is, the diameter of particles at the time when the cumulative number of fine particles as counted from smaller particles side has reached 50% of the total number of particles, is determined based on the measured data on the particle size distribution. Further, the proportion of particles having a size of not more than 10 μm on a number basis in the whole powder constituting the agglomerate can also be learned from the measured data on the particle size distribution.

In a preferred embodiment of the present invention, the 50% average particle diameter on a weight basis of the composition for a sanitary ware body per se, that is, the agglomerate, is 1 to 10 mm, more preferably 2 to 8 mm. When the 50% average particle diameter of the agglomerate is in the above-defined range, dusting is less likely to occur. Therefore, a lowering in recovery and a deterioration in work environment can be prevented. The workability at the time of transfer and reslurrying is also excellent. The 50% average particle diameter on a weight basis of the agglomerate is measured with a dry sieving device according to JIS Z 8815 (1994).

Production process of composition for sanitary ware body

In the production process of a composition for a sanitary ware body according to the present invention, water as a dispersion medium is first added to the above raw material for a sanitary ware body. The raw material for a sanitary ware body is then ground in the water to prepare a slurry for slip casting.

The amount of water added is not particularly limited. Preferably, however, water is added in such an amount that the water content of the resultant slurry is 40 to 60% by weight.

In a preferred embodiment of the present invention, in adding water, for example, a soluble salt may be further added as a deflocculant. This can modify the viscosity of the raw material slurry. Preferred examples of soluble salts include sodium silicate, sodium hydroxide, sodium carbonate, and phosphoric esters. The soluble salt is also advantageous in that clogging of the filter and deposition of flocculate can be prevented and that the pressed cake can be easily removed from the filter.

In a preferred embodiment of the invention, the raw material slurry to which water and optionally a soluble salt or the like as a deflucculant have been added is ground with a conventional grinding machine such as a ball mill to provide a 50% average particle diameter of 1 to 15 μm on a number basis.

In a preferred embodiment of the present invention, the viscosity of the ground raw material slurry is modified to a value suitable for a slurry for slip casting, for example, to a viscosity in the range of 200 to 1000 mpa·s as measured with a Brookfield viscometer at a rotor rotating speed of 60 rpm.

Next, the resultant slurry for slip casting is dehydrated and/or dried to prepare a composition for a sanitary ware body.

The slurry can be dehydrated by a conventional dehydrater such as a filter press or a centrifuge without particular limitation. Preferably, however, the dehydration is carried out by a filter press. In the filter press, a filter separates the slurry into solid matter and water.

Examples of preferred drying methods include spray drying, solar drying, warm air drying, and lyophilization. More preferred is spray drying. Spray drying using a spray dryer is advantageous in that the productivity is high by virtue of high drying speed, the particle diameter of agglomerate of the composition provided after drying is easy to control, and, further, the water content of the composition can be considerably lowered. As compared with the filter press, spray drying can more effectively prevent the loss of the soluble salt contained in the slurry and thus can be said to be a more desired solidification method for reslurrying.

In a preferred embodiment of the present invention, the slurry is dried to give a composition having a water content of 0 (zero) to 9% by weight, more preferably 3 to 7% by weight.

In another preferred embodiment of the present invention, the slurry can be dehydrated to give a pressed cake having a reduced water content of 20 to 30% by weight, which is still fluid, followed by drying to give a composition having a water content of 0 (zero) to 9% by weight, more preferably 3 to 7% by weight.

In another preferred embodiment of the present invention, a method may also be adopted wherein the slurry is dehydrated to give a pressed cake having a water content of 15 to 25% by weight which is then used as a composition for a sanitary ware body. Further, the pressed cake may be passed through a pelleter or the like to shape the cake into flakes or noodles which can improve workability and can shorten reslurrying time. The composition in the form of flakes or noodles can be dried to reduce the water content to 0 (zero) to 9% by weight. In this case, a further reduction in volume and weight can be realized, and, at the same time, since the composition is separated in a smaller size, the transfer efficiency can be enhanced.

Production process of sanitary ware using composition for sanitary ware body

In the production process of a sanitary ware according to the present invention, at the outset, at least water is added to the composition for a sanitary ware body, and the mixture is stirred to regenerate a slurry for slip casting.

Preferably, the amount of water added is properly determined so as to give proper slurry concentration and viscosity depending upon conditions of a kiln used, molding conditions such as type of a slip casting mold and the like. For example, a method may be adopted wherein the amount of water necessary for providing a predetermined slurry concentration is previously calculated from the water content of the composition and this amount of water is added to the composition for a sanitary ware body.

Mixing and stirring methods are not particularly limited, and examples thereof include stirring devices such as stirrers and blungers.

Water used for reslurrying is not particularly limited. Preferably, however, a large amount of ions which cause coagulation and precipitation, such as chloride ions (Cl⁻) or sulfate ions (SO₄²⁻), are not contained. When water used for reslurrying contains a large amount of these ions, preferably, the water is subjected to distillation or ion exchange treatment to give distilled water or ion-exchanged water which is then used for reslurrying.

In a preferred embodiment of the present invention, in reslurrying, an additional raw material powder is added in order to control shrinkage at the time of firing or casting rate at the time of slip casting. Specifically, when green bodies are fired in a plurality of kilns, the shrinkage is not often even depending upon conditions of the kilns used. Independently of the conditions of the kilns used, fired products having a given shrinkage can be prepared by adding an additional raw material powder to the regeneratred slurry to control the shrinkage at the time of firing. Since the sanitary ware includes many types and shapes, the thickness of the body should be suitable for the shape and type. The thickness of casting body at the time of slip casting can be regulated to a proper level depending upon the type and shape of the sanitary ware by adding the additional raw material powder. In particular, in the case of sanitary wares, there are various types and shapes such as toilet bowls, urinals, washbowls, and hand wash basins. Therefore, the above control of the casting thickness is effective.

In a preferred embodiment of the present invention, at least one material selected from feldspar, dolomite, and nepheline may be used as the additional raw material powder. These raw material powders function as a flux in a raw material for a sanitary ware and thus lower the melting initiation temperature of the green body at the time of firing. Therefore, when the raw material powder is added to the regenerated slurry, a proper shrinkage can be realized in firing using a kiln having a low firing temperature.

In a preferred embodiment of the present invention, at least one material selected from pottery stone, silica rock, and alumina may be used as the additional raw material powder. These raw material powders function as an aggregate in a raw material for a sanitary ware and thus increase the melting initiation temperature of the green body at the time of firing. Therefore, when the raw material powder is added to the regenerated slurry, a proper shrinkage can be realized in firing using a kiln having a high firing temperature.

In a preferred embodiment of the present invention, at least one material selected from china clay, ball clay, and plastic clay may be used as the additional raw material powder. These raw material powders function mainly to control the amount of casting at the time of slip casting and to control plasticity at the time of shaping. These additional raw material powders may also be added for viscosity modification purposes at the time of slurrying. Accordingly, the addition of these raw material powders to the regenerated slurry can realize a body having proper slurry viscosity and plasticity and can realize a body thickness suitable for the shape and type of the sanitary ware to be produced.

In a preferred embodiment of the present invention, the amount of the additional raw material powder added is 0.01 to 10 parts by weight, more preferably 0.01 to 6 parts by weight, based on 100 parts by weight of the composition for a sanitary ware body. When the amount of the additional raw material powder added is in the above-defined range, desired effects such as control of the melting initiation temperature can be attained while maintaining the high strength of the fired product.

In a preferred embodiment of the present invention, in reslurrying, a soluble salt is added for slurry viscosity modification purposes. The reason for this is as follows. The viscosity of the regenerated slurry is sometimes somewhat higher than the viscosity of the slurry before the solidification. Although the reason for this has not been fully elucidated yet, one of the reasons for this phenomenon is believed to reside in that a small amount of the soluble salt originally contained in the raw material for a sanitary ware body is lost during dehydration or drying leading to an increase in slurry viscosity. The addition of a soluble salt at the time of reslurrying can prevent the increase in viscosity to provide a slurry having a viscosity suitable for slip casting,

In a preferred embodiment of the present invention, at least one material selected from sodium silicate, sodium hydroxide, sodium carbonate, and a phosphoric ester may be used as the soluble salt. In the slurry of the raw material for a sanitary ware, these soluble salts are adsorbed to the raw material particles to have electric charges, and this results in the development of electric repulsion among the particles. Therefore, the soluble salts function as a dispersant in the slurry, and the addition of the soluble salts to the regenerated slurry can realize the control of the viscosity of the slurry toward a lower value.

In a preferred embodiment of the present invention, the amount of the soluble salt added is 0.001 to 0.2 part by weight based on 100 parts by weight of the composition for a sanitary ware body. When the amount of the soluble salt added is in the above-defined range, the viscosity of the slurry can be lowered without causing the coagulation effect.

In a preferred embodiment of the present invention, a method is adopted wherein, before the preparation of a sanitary ware using the composition for a sanitary ware body, a test piece of a sanitary ware is previously prepared using the regenerated slurry under the same process and conditions as intended to be used in the preparation of the sanitary ware and is subjected to measurement of shrinkage or the like to provide measured data based on which the regenerated slurry is slightly controled. The slight control can be carried out by properly adding various raw material powders in reslurrying the composition for a sanitary ware body. For example, when the previously measured shrinkage level of the test piece is small, a raw material powder such as feldspar, dolomite, or nepheline as a flux component for increasing the shrinkage at the time of firing is added to the slurry to render the slurry suitable for providing a proper shrinkage. On the other hand, when the previously measured shrinkage level of the test piece is large, a raw material powder such as pottery stone, silica rock and alumina as an aggregate for reducing the shrinkage at the time of firing is added to the slurry to render the slurry suitable for providing a proper shrinkage. In order to provide a body having slurry viscosity, body thickness, and plasticity suitable for the shape and type of a sanitary ware to be prepared based on data on casting amount and plasticity as measured in the preparation of the green body test piece, a raw material powder such as china clay, ball clay, and plastic clay is added to the slurry.

The regenerated slurry thus obtained is poured into a slip casting mold of gypsum or a resin, and, after casting, the resultant green body is pulled out from the mold. The green body is dried and is then coated with glaze in its desired part. The glazed green body is fired to provide a sanitary ware.

Steps after slip casting may be those commonly used in the production of sanitary wares and are not particularly limited. Any conventional glaze may be used as the glaze without limitation so far as it is suitable for the production of sanitary wares. The firing temperature is not limited so far as the temperature is suitable for the production of sanitary wares. In general, however, the firing temperature is 1100 to 1200° C.

### EXAMPLES

### Comparative Example 1

A raw material, for a sanitary ware body, containing pottery stone, feldspar, clay and the like was provided. This raw material for a sanitary ware body (800 kg), 260 kg of water, 1 kg of sodium silicate, and 720 kg of grinding balls were placed in a 1-t cylinder, and the mixture was ball milled for about 20 hr to prepare slurry A of the raw material for the body.

The content of water in slurry A was regulated to 40% by weight. Thereafter, the particle diameter of the slurry was measured with a laser diffraction-type particle size distribution analyzer. As a result, it was found that 55.3% by weight of the particles had a diameter of not more than 10 μm and the 50% average particle diameter was 8.3 μm on a number basis.

Further, the viscosity of slurry A was measured with a Brookfield viscometer at a rotor rotating speed of 60 rpm and was found to be 460 mPa·s.

Slurry A was then poured into a plaster mold, followed by slip casting to prepare a plate-shaped green body having a length of 250 mm, a width of 30 mm, and a thickness of 10 mm. This green body was dried at 45° C. overnight (about 16 hr). The dried green body was fired at 1100 to 1200° C. for 24 hr to prepare a fired product.

The dimension of the fired product was measured and was compared with the dimension of the green body immediately after the slip casting to calculate the percentage shrinkage. As a result, it was found that the percentage shrinkage was 11.5%.

The time which had elapsed between the initiation of the preparation of the raw material and the provision of the slurry for slip casting was about 30 hr.

### Comparative Example 2

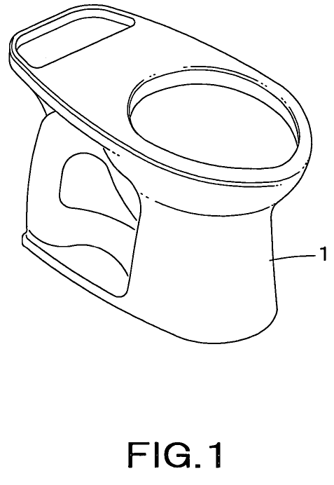

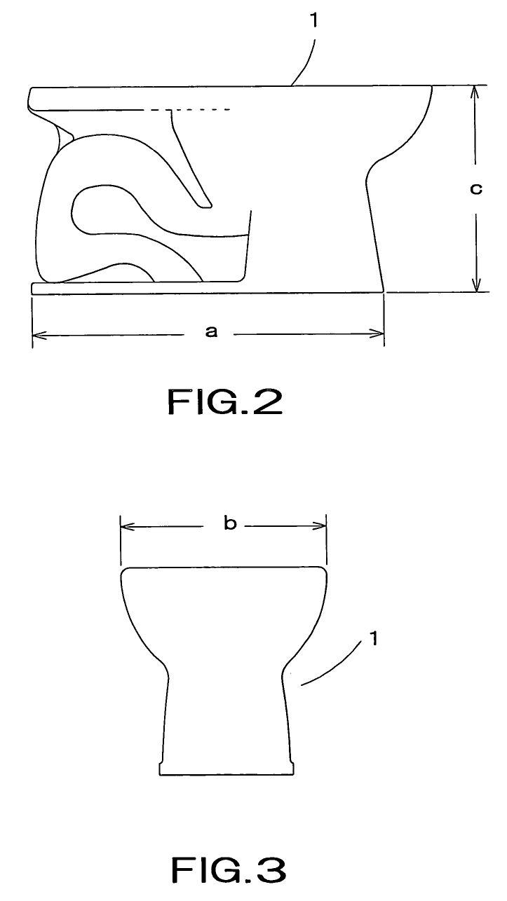

Slurry A prepared in Comparative Example 1 was poured into a plaster mold for molding a Western-style toilet bowl, followed by slip casting. The green body thus obtained was dried at 45° C. overnight (about 16 hr) and was then glazed. The glazed green body was fired at 1100 to 1200° C. for 24 hr to prepare a Western-style toilet bowl. In the same manner as described above, 10 Western-style toilet bowls were prepared. FIG. 1 is a perspective view of a Western-style toilet bowl 1 prepared in this manner, FIG. 2 is a side view of the Western-style toilet bowl 1, and FIG. 3 is a front view of the Western-style toilet bowl 1.

For each of the 10 Western-style toilet bowls prepared by the firing, the dimensions, i.e., length, width, and height, were measured to confirm whether or not the dimensions are within specifications including the tolerance of the product. The length a shown in FIG. 2 was measured as the length. The length b shown in FIG. 3 was measured as the width, and the length c shown in FIG. 2 was measured as the height. As a result, for all the Western-style toilet bowls, all the length, width and height values were located in substantially the middle of the specifications, and, thus, all the Western-style toilet bowls passed the dimensional inspection.

Further, for each of the 10 samples, the height of the green body immediately after the slip casting was compared with the height of the fired product to calculate the percentage shrinkage. As a result, the average of the percentage shrinkages was 12.4%. The length c shown in FIG. 2 was measured as the height.

### Example 1

Slurry A (about 200 kg) prepared in Comparative Example 1 was provided. This slurry A was introduced into a spray dryer and was dried and granulated by atomizing the slurry at an ambient temperature of 80° C to prepare about 120 kg of a granular composition comprising agglomerates of the powder of the raw material for the body. The water content of the composition was measured and found to be 5.5% by weight. The 50% average particle diameter on a weight basis of the composition was measured by a dry sieving apparatus according to JIS Z 8815 (1994) and found to be 2.1 mm.

The composition (2.5 kg) thus obtained, 1 kg of water, and 4 kg of grinding balls were placed in a 6 kg-earthenware pot and were mixed together and stirred in a ball mill for about 10 min to prepare regenerated slurry B. About 30 min was taken to obtain the slurry for slip casting using the solid material after the spray drying.

The content of water in slurry B was regulated to 40% by weight. Thereafter, the particle diameter of the slurry was measured with a laser diffraction-type particle size distribution analyzer. As a result, it was found that 54.8% by weight of the particles had a diameter of not more than 10 μm and the 50% average particle diameter was 8.4 μm on a number basis.

Further, the viscosity of slurry B was measured with a Brookfield viscometer at a rotor rotating speed of 60 rpm and was found to be 620 mpa·s.

Slurry B was poured into a plaster mold, followed by slip casting to prepare a plate-shaped green body having a length of 250 mm, a width of 30 mm, and a thickness of 10 mm. This green body was dried at 45° C. overnight (about 16 hr). The dried green body was fired at 1100 to 1200° C. for 24 hr to prepare a fired product.

The dimension of the fired product was measured and was compared with the dimension of the green body immediately after the slip casting to calculate the percentage shrinkage. As a result, it was found that the percentage shrinkage was 11.2%.

### Example 2

Slurry A (about 200 kg) prepared in Comparative Example 1 was provided. This slurry A was introduced into a spray dryer and was dried and granulated by atomizing the slurry at an ambient temperature of 80° C. to prepare about 120 kg of a granular composition comprising agglomerates of the powder of the raw material for the body. The water content of the composition was measured and found to be 7.0% by weight. The 50% average particle diameter on a weight basis of the composition was measured by a dry sieving apparatus according to JIS Z 8815 (1994) and found to be 2.3 mm.

The composition (2.5 kg) thus obtained, 1 kg of water, 0.5 g (0.02%) of sodium silicate, and 4 kg of grinding balls were placed in a 6 kg-earthenware pot and were mixed together and stirred in a ball mill for about 10 min to prepare regenerated slurry C. About 30 min was taken to obtain the slurry for slip casting using the composition after the spray drying.

The content of water in slurry C was regulated to 40% by weight. Thereafter, the particle diameter of the slurry was measured with a laser diffraction-type particle size distribution analyzer. As a result, it was found that 55.7% by weight of the particles had a diameter of not more than 10 μm and the 50% average particle diameter was 8.2 μm on a number basis.

Further, the viscosity of slurry C was measured with a Brookfield viscometer at a rotor rotating speed of 60 rpm and was found to be 588 mPa·s.

Slurry C was poured into a plaster mold, followed by slip casting to prepare a plate-shaped green body having a length of 250 mm, a width of 30 mm, and a thickness of 10 mm. This green body was dried at 45° C. overnight (about 16 hr). The dried green body was fired at 1100 to 1200° C. for 24 hr to prepare a fired product.

The dimension of the fired product was measured and was compared with the dimension of the green body immediately after the slip casting to calculate the percentage shrinkage. As a result, it was found that the percentage shrinkage was 11.3%.

### Example 3

Slurry A (about 200 kg) prepared in Comparative Example 1 was provided. This slurry A was introduced into a filter press apparatus. The slurry was pressed at a pressure of 10 kg/cm² and was held in this state for 30 min to dehydrate the slurry. Thus, a pressed cake having a water content of about 22% by weight was obtained. The pressed cake was fed into a pelleter (die diameter 10 mm) to provide about 160 kg of noodles of the semi-solid raw material for the body. The water content of the noodles was measured and found to be 21% by weight.

The noodles (2.5 kg) thus obtained, 700 g of water, 0.3 g (0.01%) of sodium silicate, and 4 kg of grinding balls were placed in a 6 kg-earthenware pot and were mixed together and stirred in a ball mill for about 20 min to prepare regenerated slurry D. About 50 min was taken to obtain the slurry for slip casting using the noodles.

The content of water in slurry D was regulated to 40% by weight. Thereafter, the particle diameter of the slurry was measured with a laser diffraction-type particle size distribution analyzer. As a result, it was found that 56.2% of the particles had a diameter of not more than 10 μm and the 50% average particle diameter was 8.0 μm on a number basis.

Further, the viscosity of slurry D was measured with a Brookfield viscometer at a rotor rotating speed of 60 rpm and was found to be 500 mPa·s.

Slurry D was poured into a plaster mold, followed by slip casting to prepare a plate-shaped green body having a length of 250 mm, a width of 30 mm, and a thickness of 10 mm. This green body was dried at 45° C. overnight (about 16 hr). The dried green body was fired at 1100 to 1200° C. for 24 hr to prepare a fired product.

The dimension of the fired product was measured and was compared with the dimension of the green body immediately after the slip casting to calculate the percentage shrinkage. As a result, it was found that the percentage shrinkage was 11.0%.

### Example 4

Slurry A (about 200 kg) prepared in Comparative Example 1 was provided. This slurry A was introduced into a spray dryer and was dried and granulated by atomizing the slurry at an ambient temperature of 80° C. to prepare about 120 kg of a granular composition comprising agglomerates of the powder of the raw material for the body. The water content of the composition was measured and found to be 7.0% by weight. The 50% average particle diameter on a weight basis of the composition was measured by a dry sieving apparatus according to JIS Z 8815 (1994) and found to be 2.2 mm.

The composition (2.5 kg) thus obtained, 1 kg of water, 0.5 g (0.02%) of sodium silicate, 4 kg of grinding balls, and 125 g of feldspar were placed in a 6 kg-earthenware pot and were mixed together and stirred in a ball mill for about 10 min to prepare regenerated slurry E. About 35 min was taken to obtain the slurry for slip casting using the composition after the spray drying.

The content of water in slurry E was regulated to 40% by weight. Thereafter, the particle diameter of the slurry was measured with a laser diffraction-type particle size distribution analyzer. As a result, it was found that 55.0% of the particles had a diameter of not more than 10 μm and the 50% average particle diameter was 8.0 μm on a number basis.

Further, the viscosity of slurry E was measured with a Brookfield viscometer at a rotor rotating speed of 60 rpm and was found to be 540 mPa·s.

Slurry E was poured into a plaster mold, followed by slip casting to prepare a plate-shaped green body having a length of 250 mm, a width of 30 mm, and a thickness of 10 mm. This green body was dried at 45° C. overnight (about 16 hr). The dried green body was fired at 1100 to 1200° C. for 24 hr to prepare a fired product.

The dimension of the fired product was measured and was compared with the dimension of the green body immediately after the slip casting to calculate the percentage shrinkage. As a result, it was found that the percentage shrinkage was 12.2%.

### Example 5

Slurry A (about 200 kg) prepared in Comparative Example 1 was provided. This slurry A was introduced into a spray dryer and was dried and granulated by atomizing the slurry at an ambient temperature of 80° C. to prepare about 120 kg of a granular composition comprising agglomerates of the powder of the raw material for the body. The water content of the composition was measured and found to be 7.0% by weight. The 50% average particle diameter on a weight basis of the composition was measured by a dry sieving apparatus according to JIS Z 8815 (1994) and found to be 2.1 mm.

The composition (2.5 kg) thus obtained, 1 kg of water, 1.5 g (0.06%) of sodium silicate, and 4 kg of grinding balls were placed in a 6 kg-earthenware pot and were mixed together and stirred in a ball mill for about 10 min to prepare regenerated slurry F. About 35 min was taken to obtain the slurry for slip casting using the powder after the spray drying.

The content of water in slurry F was regulated to 40% by weight. Thereafter, the particle diameter of the slurry was measured with a laser diffraction-type particle size distribution analyzer. As a result, it was found that 55.7% of the particles had a diameter of not more than 10 μm and the 50% average particle diameter was 8.2 μm on a number basis.

Further, the viscosity of slurry F was measured with a Brookfield viscometer at a rotor rotating speed of 60 rpm and was found to be 460 mPa·s.

Slurry F was poured into a plaster mold, followed by slip casting to prepare a plate-shaped green body having a length of 250 mm, a width of 30 mm, and a thickness of 10 mm. This green body was dried at 45° C. overnight (about 16 hr). The dried green body was fired at 1100 to 1200° C. for 24 hr to prepare a fired product.

The dimension of the fired product was measured and was compared with the dimension of the green body immediately after the slip casting to calculate the percentage shrinkage. As a result, it was found that the percentage shrinkage was 11.4%.

### Example 6

Slurry G (12 t) was prepared in the same manner as in Comparative Example 1, except that the proportion of the components in the raw material for a sanitary ware body was varied. This slurry G was introduced into a spray dryer and was dried and granulated by atomizing the slurry at an ambient temperature of 80° C. to prepare about 11 t of a granular composition comprising agglomerate of the powder of the raw material for the body. The water content of the powder was measured and found to be 4.5% by weight. The 50% average particle diameter on a weight basis of the composition was measured by a dry sieving apparatus according to JIS Z 8815 (1994) and found to be 2.1 mm.

The composition (5.0 t) thus obtained, 2.0 t of water, 1.0 kg (0.02%) of sodium silicate, and 4800 kg of grinding balls were placed in a 5 t-cylinder and were mixed together and stirred in a cylinder mill for about 30 min to prepare regenerated slurry H. About 55 min was taken to obtain the slurry for slip casting using the composition after the spray drying.

The content of water in slurry H was regulated to 40% by weight. Thereafter, the particle diameter of the slurry was measured with a laser diffraction-type particle size distribution analyzer. As a result, it was found that 53.6% of the particles had a diameter of not more than 10 μm and the 50% average particle diameter was 8.6 μm on a number basis.

Further, the viscosity of slurry H was measured with a Brookfield viscometer at a rotor rotating speed of 60 rpm and was found to be 484 mPa·s.

Slurry H was poured into the same plaster mold as used in Comparative Example 2, followed by slip casting. The green body thus obtained was dried and was then glazed. The glazed green body was fired at 1100 to 1200° C. for 24 hr to prepare a Western-style toilet bowl. In the same manner as described above, 10 Western-style toilet bowls were prepared.

For each of the 10 Western-style toilet bowls prepared by the firing, the dimensions, i.e., length, width, and height, were measured in the same manner as in Comparative Example 2 to confirm whether or not the dimensions are within specifications including the tolerance of the product. As a result, all the Western-style toilet bowls passed the dimensional inspection, although all the length, width and height values were those close to the respective upper limits of the specifications including the tolerance.

Further, in the same manner as in Comparative Example 2, for each of the 10 samples, the height of the green body immediately after the slip casting was compared with the height of the. fired product to calculate the percentage shrinkage. As a result, the average of the percentage shrinkages was 11.3%.

Example 7

China clay (200 kg), 50 kg of gairome clay, and 50 kg of feldspar powder were added to 5.0 t of the composition prepared by the spray dryer in Example 6. The mixture, together with 2.0 t of water, 1.0 kg (0.02%) of sodium silicate, and 4800 kg of grinding balls were placed in a 5 t-cylinder and were mixed together and stirred in a cylinder mill for about 30 min to prepare regenerated slurry J. About 60 min was taken to obtain the slurry for slip casting using the composition after the spray drying.

The content of water in slurry J was regulated to 40% by weight. Thereafter, the particle diameter of the slurry was measured with a laser diffraction-type particle size distribution analyzer. As a result, it was found that 54.9% of the particles had a diameter of not more than 10 μm and the 50% average particle diameter was 8.2 μm on a number basis.

Further, the viscosity of slurry J was measured with a Brookfield viscometer at a rotor rotating speed of 60 rpm and was found to be 598 mPa·s.

Slurry J was poured into the same plaster mold as used in Comparative Example 2, followed by slip casting. The green body thus obtained was dried and was then glazed. The glazed green body was fired at 1100 to 1200° C. for 24 hr to prepare a Western-style toilet bowl. In the same manner as described above, 10 Western-style toilet bowls were prepared.

For each of the 10 Western-style toilet bowls prepared by the firing, the dimensions, i.e., length, width, and height, were measured in the same manner as in Comparative Example 2 to confirm whether or not the dimensions are within specifications including the tolerance of the product. As a result, for all the Western-style toilet bowls, all the length, width and height values were located in substantially the middle of the specifications, and, thus, all the Western-style toilet bowls passed the dimensional inspection.

Further, in the same manner as in Comparative Example 2, for each of the 10 samples, the height of the green body immediately after the slip casting was compared with the height of the fired product to calculate the percentage shrinkage. As a result, the average of the percentage shrinkages was 12.2%.

### RESULTS

Various measured values for Comparative Example 1 and Examples 1 to 5 are shown in Table 1.

TABLE 1

| | Comp. Ex. 1 | Ex. 1 | Ex. 2 | Ex. 3 | Ex. 4 | Ex. 5 |
|---|---|---|---|---|---|---|
| Water content of composition | — | 5.5% | 7.0% | 21.0% | 7.0% | 7.0% |
| Slurry preparation time | 30 hr | 30 min | 30 min | 50 min | 35 min | 35 min |
| Properties of slurry | | | | | | |
| Particle diameter < 10 μm | 55.3% | 54.8% | 55.7% | 56.2% | 55.0% | 55.7% |
| 50% average particle diameter | 8.3 μm | 8.4 μm | 8.2 μm | 8.0 μm | 8.0 μm | 8.2 μm |
| Viscosity | 460 mPa · s | 620 mPa · s | 588 mPa · s | 500 mPa · s | 540 mPa · s | 460 mPa · s |
| Firing time | 24 hr | 24 hr | 24 hr | 24 hr | 24 hr | 24 hr |
| Firing shrinkage | 11.5% | 11.2% | 11.3% | 11.0% | 12.2% | 11.4% |

The following facts can be seen from the results shown in Table 1. For Examples 1 to 5, the properties of slurry regenerated from the granular compositions and the percentage shrinkage of the samples prepared using the regenerated slurries were substantially equal to those of as-prepared slurries in Comparative Example 1 which had not been brought into a granular composition. This demonstrates that the composition for a sanitary ware body according to the present invention has a high level of suitability for slurry regeneration and can be advantageously used in slip casting of sanitary wares. Further, comparison of the slurry preparation time in Comparative Example 1 with the slurry preparation time in Examples 1 to 5 shows that the present invention can 15 significantly shorten the slurry preparation time.

For Comparative Example 2 and Examples 6 and 7, various measured values are shown in Table 2.

TABLE 2

| | Comp. Ex. 2 | Ex. 6 | Ex. 7 |
|---|---|---|---|
| Water content of | — | 4.5% | 4.5% |
| composition | | | |
| Slurry preparation time | 30 hr | 55 min | 60 min |
| Properties of slurry | | | |
| Particle diameter < | 55.3% | 53.6% | 54.9% |
| 10 μm | | | |
| 50% average particle | 8.3 μm | 8.6 μm | 8.2 μm |
| diameter | | | |
| Viscosity | 460 mPa · s | 484 mPa · s | 598 mPa · s |
| Firing time | 24 hr | 24 hr | 24 hr |
| Firing shrinkage | 12.4% | 11.3% | 12.2% |
| Dimensional inspection | Passed | Passed | Passed |

The following facts can be seen from the results shown in Table 2. For Examples 6 and 7, the properties of slurries regenerated from the granular compositions and the firing shrinkage and dimensional accuracy of the sanitary wares prepared using the regenerated slurries were substantially equal to those of as-prepared slurries in Comparative Example 2 which had not been brought into a granular composition. This demonstrates that the composition for a sanitary ware body according to the present invention has a high level of suitability for slurry regeneration and can be advantageously used in slip casting of sanitary wares. Specifically, when the composition for a sanitary ware body according to the present invention is used in the production of a sanitary ware, the sanitary ware can be produced under the same casting and firing conditions as used in the production of a sanitary ware using the slurry before the solidification. Further, comparison of the slurry preparation time in Comparative Example 2 with the slurry preparation time in Examples 6 and 7 shows that the present invention can significantly shorten the slurry preparation time.

1. A non-slurry composition for a sanitary ware body for use in preparing a slurry for slip casting, comprising agglomerates of a raw material powder for said sanitary ware body and having a water content of 0 (zero) to 25% by weight, wherein said powder has a 50% average particle diameter of 1 to 15 μm on a number basis.

2. The composition for a sanitary ware body according to claim 1, wherein said water content is 0 (zero) to 9% by weight.

3. The composition for a sanitary ware body according to claim 1, wherein said water content is 3 to 7% by weight.

4. The composition for a sanitary ware body according to claim 1, wherein said water content is 15 to 25% by weight.

5. The composition for a sanitary ware body according to claim 1, wherein the 50% average particle diameter of the agglomerates is 1 to 10 mm on a weight basis.

6. A process for producing a non-slurry composition for a sanitary ware body for use in preparing a slurry for slip casting, said process comprising the steps of:
providing a raw material for a sanitary ware body; adding water to the raw material for a sanitary ware body;
grinding the raw material for a sanitary ware body with water added thereto to prepare a slurry for slip casting; and
dehydrating and/or drying the slurry for slip casting to prepare the composition for a sanitary ware body.

7. The process according to claim 6, wherein, in adding said water, a soluble salt for viscosity of the slurry is further added to material for a sanitary ware body.

8. The process according to claim 7, wherein said soluble salt is at least one salt selected from the group consisting of sodium silicate, sodium hydroxide, sodium carbonate, and a phosphoric ester.

9. The process according to claim 6, wherein said drying is carried out by a spray dryer.

10. The process according to claim 6, wherein said dehydration is carried out by a filter press.

11. The process according to claim 6 any one of claims 6, wherein the viscosity of the slurry for slip casting is 200 to 1,000 mPa·s as measured with a Brookfield viscometer at a rotor rotating speed of 60 rpm.

12. A composition for a sanitary ware body, which is produced by a process according to claim 6.

13. A process for producing a sanitary ware, comprising the steps of:
adding water to the composition for a sanitary ware body according to claim 1 and stirring the mixture to regenerate the slurry;
pouring the slurry into a slip casting mold and allowing the slurry to cast on the mold;
taking the resultant green body out of the mold; drying the green body;
coating glaze onto the dried green body; and firing the glaze-coated green body.

14. The process according to claim 13, wherein, in adding said water, an additional raw material powder is further added for regulating the percentage shrinkage at the time of said firing or for regulating casting rate at the time of said slip casting.

15. The process according to claim 14, wherein said additional raw material powder is at least one material selected from the group consisting of feldspar, dolomite, and nepheline.

16. The process according to claim 14, wherein said additional raw material powder is at least one material selected from the group consisting of pottery stone, silica rock, and alumina.

17. The process according to claim 14, wherein said additional raw material powder is at least one material selected from the group consisting of china clay, ball clay, and plastic clay.

18. The process according to claim 14, wherein the amount of the additional raw material powder added is 0.01 to 10 parts by weight based on 100 parts by weight of the composition for a sanitary ware body.

19. The process according to claim 14, wherein, in adding said water, a soluble salt is further added for modifying the viscosity of the slurry.

20. The process according to claim 19, wherein said soluble salt is at least one salt selected from the group consisting of sodium silicate, sodium hydroxide, sodium carbonate, and a phosphoric ester.

21. The process according to claim 19, wherein the amount of the soluble salt added is 0.001 to 0.2 part by weight based on 100 parts by weight of the composition for a sanitary ware body.

22. A sanitary ware produced by the process according to claim 13.

23. Use of the composition for a sanitary ware body according to claim 1, for the production of a sanitary ware.

24. The composition for a sanitary ware body according to claim 1, wherein said water content is less than 20% by weight.
